(19) United States
(12) Patent Application Publication
(10) Pub. No.: US 2025/0098067 A1
(43) Pub. Date: Mar. 20, 2025

(54) PRINTED CIRCUIT BOARD

(71) Applicant: SAMSUNG ELECTRO-MECHANICS CO., LTD., Suwon-si (KR)

(72) Inventors: Chi Hyeon JEONG, Suwon-si (KR); Jin Uk LEE, Suwon-si (KR); Hyun Sang KWAK, Suwon-si (KR); Seok Hwan KIM, Suwon-si (KR)

(73) Assignee: SAMSUNG ELECTRO-MECHANICS CO., LTD., Suwon-si (KR)

(21) Appl. No.: 18/592,291

(22) Filed: Feb. 29, 2024

(30) Foreign Application Priority Data
Sep. 19, 2023 (KR) 10-2023-0124490

(51) Int. Cl. H05K 1/11; H05K 3/42

(52) U.S. Cl. CPC H05K 1/115; H05K 3/429; H05K 2201/09563; H05K 2201/09827; H05K 2203/049

(57) ABSTRACT

The present disclosure relates to a printed circuit board including: an insulating layer; a through-hole penetrating between an upper surface and a lower surface of the insulating layer opposing in a thickness direction; a metal wiring disposed inside the through-hole; and a metal via filling the through-hole and covering the metal wire.

### CROSS-REFERENCE TO RELATED APPLICATION(S)

This application claims the benefit of priority to Korean Patent Application No. 10-2023-0124490, filed on Sep. 19, 2023 in the Korean Intellectual Property Office, the disclosure of which is incorporated herein by reference in its entirety.

### TECHNICAL FIELD

The present disclosure relates to a printed circuit board.

### BACKGROUND

Package technology continues to develop, and specifically, a traditional substrate manufacturing method continues to attempt to use silicon or glass to break away from the use of organic materials. Glass is known to have better warpage properties and planarization than conventional organic materials, which may be advantageous for reducing a line and a space of traces. However, when manufacturing a substrate with a current glass core, it may be difficult to form a through-via in a thick glass core. For example, a seed layer may be required to proceed with plating in a via hole, but because a glass surface is smooth and the via hole has a high aspect ratio, it may be difficult to form a seed. In addition, when forming a seed using a sputtering process or the like, it may take a significant amount of time and costs to form a seed having a desired thickness.

### SUMMARY

An aspect of the present disclosure is to provide a printed circuit board that may improve the quality of a substrate by suppressing the formation of voids or seams even when fill plating is performed on a through-hole having a high aspect ratio, such as a through-hole formed in a glass substrate.

Another aspect of the present disclosure is to provide a printed circuit board that may minimize costs by omitting the formation of a metal seed layer in a through-hole having a high aspect ratio, such as a through-hole formed in a glass substrate.

One of the various solutions proposed through the present disclosure is to form a through-hole in an insulating layer such as a glass substrate, insert and seat a metal wire inside the through-hole, and then perform fill plating with a metal wire as a seed layer in the through-hole, thereby forming a metal via covering the metal wire.

According to an aspect of the present disclosure, a printed circuit board may include: an insulating layer; a through-hole penetrating between an upper surface and a lower surface of the insulating layer opposing in a thickness direction; a metal wire disposed inside the through-hole; and a metal via filling the through-hole and covering the metal wire.

According to another aspect of the present disclosure, a printed circuit board may include: an insulating layer having a through-hole; a metal wire disposed inside the through-hole; a first metal layer filling the through-hole and covering the metal wire; a first seed metal layer disposed on an upper surface of each of the insulating layer and the first metal layer; a second seed metal layer disposed on a lower surface of each of the insulating layer and the first metal layer; a second metal layer disposed on an upper surface of the first seed metal layer; and a third metal layer disposed on a lower surface of the second seed metal layer.

According to still another aspect of the present disclosure, a printed circuit board may include: an insulating layer; a through-hole penetrating between an upper surface and a lower surface of the insulating layer opposing in a thickness direction; a first metal portion disposed inside the through-hole; and a second metal portion filling the through-hole and covering the first metal portion, in which a thickness of the first metal portion in the thickness direction is larger than a width of the first metal portion in a width direction perpendicular to the thickness direction.

One effect of the present disclosure is to provide a printed circuit board that may improve the quality of a substrate by suppressing the formation of voids or seams even when fill plating is performed on a through-hole having a high aspect ratio, such as a through-hole formed in a glass substrate.

Another effect of the present disclosure is to provide a printed circuit board that may minimize process time and costs by omitting the formation of a metal seed layer in a through-hole having a high aspect ratio, such as a through-hole formed on a glass substrate.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating an example of a printed circuit board;

FIGS. 4A to 4G are process cross-sectional views schematically illustrating an example of manufacturing the printed circuit board of FIG. 3;

FIG. 5 is a cross-sectional view schematically illustrating the other example of a printed circuit board; and

FIG. 6 is a cross-sectional view schematically illustrating another example of a printed circuit board.

### DETAILED DESCRIPTION

Hereinafter, the present disclosure will be described with reference to the accompanying drawings. In the drawings, the shape and size of the elements may be exaggerated or reduced for clearer description.

### Electronic Device

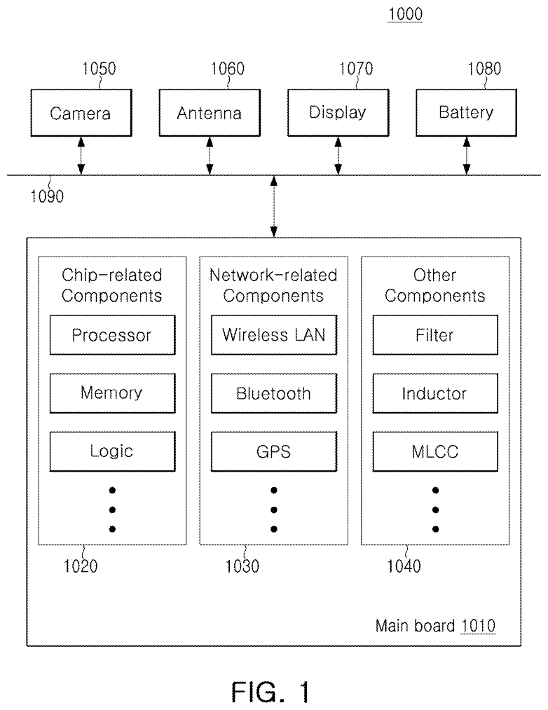

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may be in the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), long term IEEE 802.20, evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), or the like. However, other components are not limited thereto, and may also include passive components in the form of chip components used for various other purposes. In addition, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. Furthermore, these other electronic components may also other electronic components used for various purposes depending on a type of electronic device 1000.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component. However, the electronic device 1000 is not limited thereto, and may be any other electronic device that processes data in addition thereto.

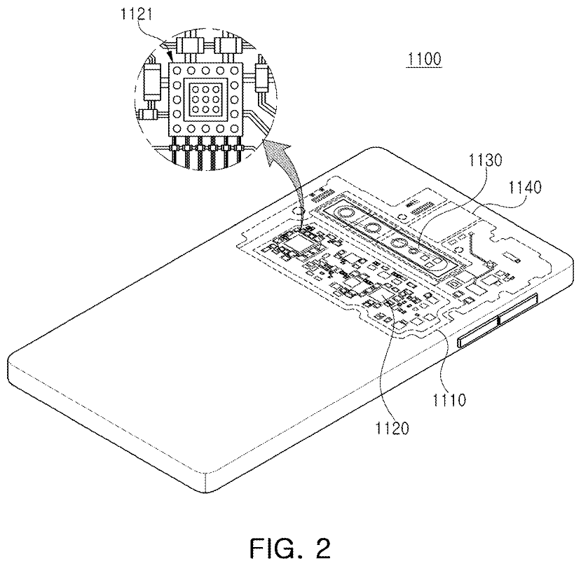

FIG. 2 is a perspective view schematically illustrating an example of an electronic device.

Referring to FIG. 2, an electronic device may be, for example, a smartphone 1100. A mother board 1110 may be accommodated in the smartphone 1100, and various components 1120 may be physically and/or electrically connected to the mother board 1110. Furthermore, other components that may or may not be physically and/or electrically connected to the mother board 1110, such as a camera module 1130 and/or a speaker 1140, may be accommodated in the smartphone 1100. Some of the components 1120 may be the chip-related components described above, for example, the component package 1121, but the present disclosure is not limited thereto. The component package 1121 may be in the form of a printed circuit board in which an electronic component including an active component and/or a passive component is mounted on a surface. Alternatively, the component package 1121 may be in the form of a printed circuit board in which an active component and/or a passive component are embedded. On the other hand, the electronic device is not necessarily limited to the smartphone 1100, and may be other electronic devices as described above.

### Printed Circuit Board

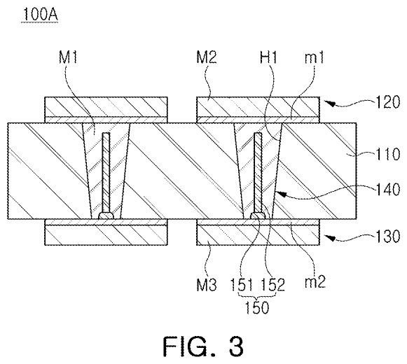

FIG. 3 is a cross-sectional view schematically illustrating an example of a printed circuit board.

Referring to FIG. 3, a printed circuit board 100A according to an example embodiment may include an insulating layer 110, a through-hole H1 penetrating between an upper surface and a lower surface of the insulating layer 110, a metal wire 150 disposed in the through-hole H1, a metal via 140 filling the through-hole H1 and covering the metal wire 150, a first metal wiring 120 disposed on the upper surface of the insulating layer 110 and connected to an upper end of the metal via 140, and a second metal wiring 130 disposed on the lower surface of the insulating layer 110 and connected to a lower end of the metal via 140. The through-hole H1 may be tapered so that a width of the upper end thereof is wider than a width of a lower end thereof on a cross-section. The metal wire 150 may include a bonding portion 151 and a wire portion 152 connected to the bonding portion 151.

As described above, when the printed circuit board 100A according to an example embodiment forms the metal via 140 having a high aspect ratio in the insulating layer 110 having a considerable thickness, like a glass substrate, the metal wire 150 is inserted into the through-hole H1 in advance, and then plating is performed. For example, after inserting the metal wire 150, the through-hole H1 may be filled using fill plating or the like. Accordingly, it may be possible to effectively suppress an occurrence of voids or seams in the through-hole H1. Therefore, the quality of the substrate may be further improved.

Meanwhile, the metal via 140 may include a first metal layer M1 filling the through-hole H1 and covering the metal wire 150, but may not include a seed metal layer. For example, the first metal layer M1 may be a single layer formed of electroplating (or electrocoating), and the first metal layer M1 may be in contact with a wall surface of the through-hole H1. For example, the metal wire 150 may serve as a seed for plating the first metal layer M1. Accordingly, process time and costs may be minimized by omitting a seed process. On the other hand, when an end of the wire portion 152 is disposed on an upper level than a center of the insulating layer 110 and an upper surface of the insulating layer 110 based on a thickness direction, this may more effectively perform the seed role described above. If necessary, an end of the wire portion 152 may be placed on a lower level than the upper surface of the insulating layer 110 based on the thickness direction, and in this case, the metal wire 150 may be more stably seated in the through-hole H1. However, the present disclosure is not limited thereto, and the end of the wire portion 152 may protrude above the upper surface of the insulating layer 110 and may be covered with the first metal wiring 120. Meanwhile, an end may denote an uppermost portion of the wire portion 152 on a cross-section.

Meanwhile, the first metal layer M1, for example, an upper surface and a lower surface of the metal via 140, may be substantially coplanar with the upper surface and the lower surface of the insulating layer 110, respectively. Furthermore, a lower surface of the bonding portion 151 of the metal wire 150 may be substantially coplanar with the first metal layer M1, for example, the lower surface of the metal via 140 and the lower surface of the insulating layer 110. For example, by disposing the metal wire 150 in the through-hole H1 of the insulating layer 110 using a carrier and performing the plating, after removing a carrier, lower sides thereof may be coplanar with each other as described above. Furthermore, after filling the through-hole H1 of the insulating layer 110 with plating to form the first metal layer M1, for example, the metal via 140, a planarization process may be performed as necessary, from which upper sides thereof may be coplanar with each other as described above. In this case, the first and second metal wirings 120 and 130 may be formed more easily by minimizing undulation, and a build-up layer may be formed more easily on both sides of the insulating layer 110 as necessary.

Meanwhile, the first metal wiring 120 may include a first seed metal layer m1 disposed on an upper surface of each of the insulating layer 110 and the metal via 140 to cover them, and a second metal layer M2 disposed on an upper surface of the first seed metal layer m1 to cover the first seed metal layer m1 and configured to be thicker than the first seed metal layer m1. Furthermore, the second metal wiring 130 may include a second seed metal layer m2 disposed on a lower surface of each of the insulating layer 110, the metal via 140 and the metal wire 150 to cover them, and a third metal layer M3 disposed on a lower surface of the second seed metal layer m2 to cover the second seed metal layer m2 and configured to be thicker than the second seed metal layer m2. For example, the first and second metal wirings 120 and 130 may be formed in a planarized region through a plating process. Meanwhile, a lower surface of the bonding portion 151 of the metal wire 150 may be in contact with the second seed metal layer m2. Furthermore, an upper surface of the wire portion 152 of the metal wire 150 may be spaced apart from the first seed metal layer m1, but the present disclosure is not limited thereto, and the upper surface thereof may come into contact with the first seed metal layer m1, if necessary.

Meanwhile, the printed circuit board 100A according to an example embodiment may be applied as any one layer of a multilayer circuit board. For example, a core layer of a multilayer circuit board may be applied, and in this case, a build-up process may be performed on one side or both sides of the printed circuit board 100A. The multilayer circuit board may be used as Film-Chip Board (FCB), Ball Grid Array (BGA), an interposer substrate, and a package substrate. However, the present disclosure is not limited thereto, and the multilayer circuit board may be applied to other various types of substrates.

Hereinafter, components of the printed circuit board 100A according to an example embodiment will be described in more detail with reference to the drawings.

The insulating layer 110 may include an insulating material. The insulating material may include an inorganic insulating material, and the inorganic insulating material may be, for example, glass, ceramic, silicon, or the like, but is not limited thereto. The inorganic insulating material may include, preferably, glass. For example, the insulating layer 110 may include a glass substrate. The glass substrate may include glass that is an amorphous solid. Glass may include, for example, pure silicon dioxide (about 100% SiO₂), soda lime glass, borosilicate glass, and alumino-silicate glass. However, the present disclosure is not limited thereto, and alternative glass materials, such as fluorine glass, phosphoric acid glass, chalcogen glass, and the like, may also be used as materials. Other additives may also be included to form glass having specific physical properties. These additives may include magnesium, calcium, manganese, aluminum, lead, boron, iron, chromium, potassium, sulfur, and antimony, as well as calcium carbonate (e.g., lime) and sodium carbonate (e.g., soda). The glass substrate may be a layer distinct from organic insulation materials including glass fibers (Glass Fiber, Glass Cloth and Glass Fabric), such as Copper Clad Laminate (CCL) and Prepreg (PPG). For example, the glass substrate may be a plate glass.

Meanwhile, if necessary, the insulating layer 110 may have a multilayer structure. For example, the insulating layer 110 may have a structure in which organic insulating layers are formed on both sides of the glass substrate. The organic insulating layer may include an organic insulating material, and the organic insulating material may include a thermosetting resin such as an epoxy resin, a thermoplastic resin such as polyimide, or a material including inorganic fillers, organic fillers, and/or glass fibers (Glass Fiber, Glass Cloth and Glass Fabric) together with these resins. For example, the organic insulation material may be non-photosensitive insulation materials such as Prepreg (PPG) and an Ajinomoto Build-up Film (ABF), but the present disclosure is not limited thereto, and a photosensitive insulation material or other polymer materials may be used.

Each of the first and second metal wirings 120 and 130 may include a metallic material. The metallic material may include copper (Cu), aluminum (Al), silver (Ag), tin (Sn), gold (Au), nickel (Ni), lead (Pb), titanium (Ti), and/or alloys thereof. For example, each of the first and second seed metal layers m1 and m2 and the first and second metal layers M1 and M2 of the first and second metal wirings 120 and 130 may include the above-described metallic material, and may include, preferably, copper (Cu), but the present disclosure is not limited thereto. Each of the first and second metal wirings 120 and 130 may perform various functions according to a design. For example, the first and second metal wirings 120 and 130 may include a signal pattern, a power pattern, a ground pattern. Each of these patterns may have various shapes such as a line, a plane, and a pad. The first and second seed metal layers m1 and m2 may be formed by sputtering, but are not limited thereto, and may be formed by electroless plating (or chemical copper) if necessary. The second and third metal layers M2 and M3 may be formed by electroplating (or electro-coating).

The metal via 140 may include a metallic material. The metallic material may include copper (Cu), aluminum (Al), silver (Ag), tin (Sn), gold (Au), nickel (Ni), lead (Pb), titanium (Ti), and/or alloys thereof. For example, the first metal layer M1 of the metal via 140 may include the aforementioned metal material, and preferably may include copper (Cu), but the present disclosure is not limited thereto. The metal via 140 may perform various functions according to a design. For example, the metal via 140 may include a ground via, a power via, and a signal via. The metal via 140 may be formed by electroplating (or electrocoating) using the metal wire 150 as a seed without a separate other seed metal layer.

The metal wire 150 may include a metal material. The metal material may include copper (Cu), gold (Au), silver (Ag), palladium (Pd), and/or alloys thereof. For example, the metal wire 150 may include a palladium (Pd)-copper (Cu) alloy, but is not limited thereto. The metal wire 150 may include a bonding portion 151 and a wire portion 152, each of which may include the same metal material. The metal wire 150 may be spaced apart from a wall surface of the through-hole H1. For example, a size of the metal wire 150 may be determined according to a size of the through-hole H1.

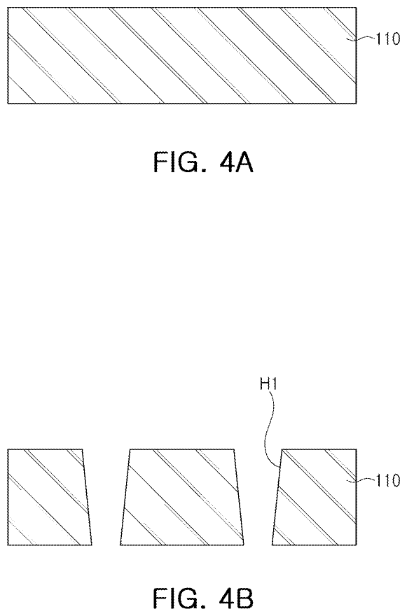

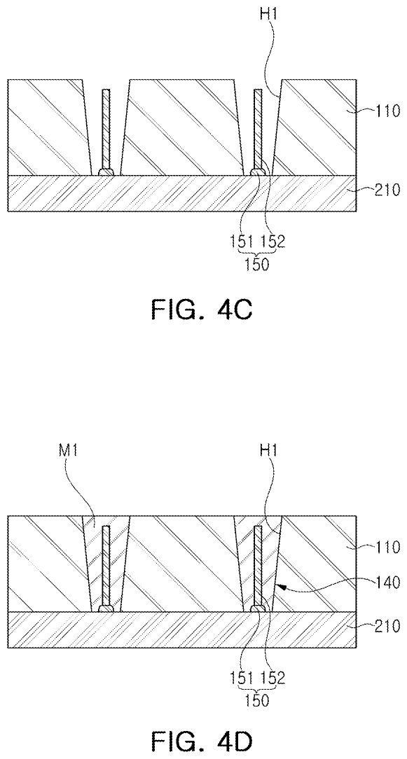

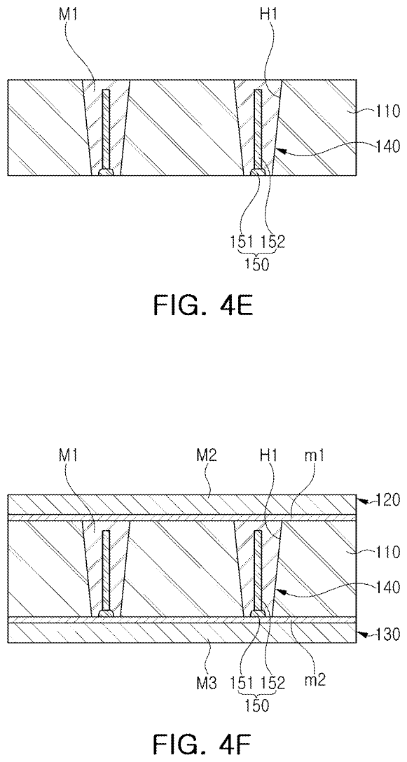

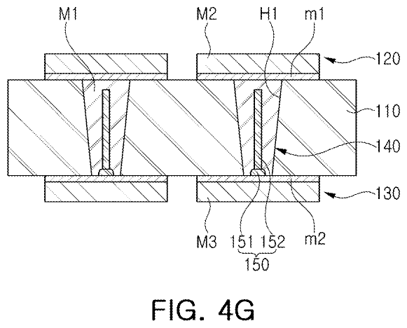

FIGS. 4A to 4G are process cross-sectional views schematically illustrating an example of manufacturing the printed circuit board of FIG. 3.

Referring to the drawings, in FIG. 4A, an insulating layer 110 is prepared. As described above, the insulating layer 110 may be a glass substrate such as plate glass. Next, in FIG. 4B, a through-hole H1 is formed on the insulating layer 110. The through-hole H1 may be formed to be tapered by etching after disposing a mask on the insulating layer, for example, an upper surface of the glass layer, but the present disclosure is not limited thereto, and for example, other chemical methods or mechanical methods may be used to form the through-hole H1. A plurality of through-holes H1 may be formed, and each of the through-holes H1 may be identical or different. Next, in FIG. 4C, the metal wire 150 is inserted into the through-hole H1. For example, after attaching the metal wire 150 to a carrier 210 in advance, the insulation layer 110 may be stacked so that the metal wire 150 is inserted into the through-hole H1. Next, in FIG. 4D, a first metal layer M1 is formed in the through-hole H1. The first metal layer M1 may be formed by fill plating using the metal wire 150 as a seed. As a result, the metal via 140 may be formed. Next, in FIG. 4E, the carrier 210 is removed. For example, the carrier 210 may be physically separated. Thereafter, if necessary, a planarization process may be performed. Next, in FIG. 4F, first and second seed metal layers m1 and m2 and second and third metal layers M2 and M3 are formed on both sides of the insulating layer 110, the metal via 140, and the metal wire 150. The first and second seed metal layers m1 and m2 may be formed by a sputtering process, and the second and third metal layers M2 and M3 may be formed by electroplating (or electric copper). Next, in FIG. 4G, first and second metal wirings 120 and 130 are formed. For example, patterning may be performed by etching to form the first and second metal wirings 120 and 130. For example, a tenting (TT) process may be used. However, the present disclosure is not limited thereto, and the processes of FIGS. 4F and 4G may be replaced by an additive process (AP) and a semi additive process (SAP). The printed circuit board 100A according to the above-described example embodiment may be formed through a series of processes, and other contents are substantially the same as described above, and thus overlapping descriptions thereof will be omitted.

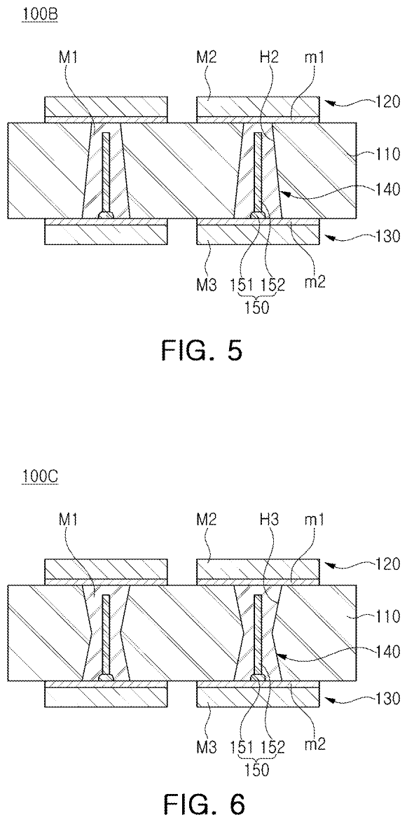

FIG. 5 is a cross-sectional view schematically illustrating the other example of a printed circuit board.

Referring to FIG. 5, in a printed circuit board 100B according to the other example embodiment, a through-hole H2 may have a tapered shape so that a width of a lower end thereof is wider than a width of an upper end on a cross-section, in the printed circuit board 100A according to the above-described example embodiment. Other contents are substantially the same as described above, and thus overlapping descriptions thereof are omitted.

FIG. 6 is a cross-sectional view schematically illustrating another example of a printed circuit board.

Referring to FIG. 6, in a printed circuit board 100A according to another example embodiment, a through-hole H3 may have a tapered shape on both sides so that a width of each of an upper end and a lower end thereof is wider than a width of a certain interior between the upper end and the lower end thereof. For example, the through-hole H3 may have an hourglass shape. Other contents are substantially the same as described above, and thus overlapping descriptions thereof are omitted.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of approximately filling, and may include, for example, a case in which some pores or voids exist.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, a thickness, a width, a length, and a depth may be measured by a scanning microscope or an optical microscope based on a cross-section obtained by polishing or cutting a printed circuit board, respectively. The cut cross-section may be a vertical cross-section or a horizontal cross-section, and each numerical value may be measured based on a required cut cross-section. When the value is not constant, the value may be determined as an average value of values measured at any five points. A width of the upper end and/or the lower end of the through-hole may be measured on a cross-section in which a central axis of the through-hole in a substrate is cut in a thickness direction. A depth of the through-hole may be measured by a distance from an upper end to a lower end of each object on a cross-section in which a central axis of each object in the substrate is cut in the thickness direction.

In the present disclosure, a lower side, a lower portion, and a lower surface are used to refer to a downward direction with respect to a cross-section of a drawing, and an upper side, an upper portion, and an upper surface are used to refer to an opposite direction thereof. However, this defines the direction for convenience of explanation, and the scope of the rights of the claims is not particularly limited by the description of such a direction, and the concept of upper and lower portions may be changed at any time.

In the present disclosure, a meaning of being connected is a concept including not only directly connected but also indirectly connected through an adhesive layer or the like. Furthermore, a meaning of electrically connected is a concept including both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board comprising:
an insulating layer;
a through-hole penetrating between an upper surface and a lower surface of the insulating layer opposing in a thickness direction;
a metal wire disposed inside the through-hole; and
a metal via filling the through-hole and covering the metal wire.

2. The printed circuit board according to claim 1, wherein the metal wire includes a bonding portion and a wire portion connected to the bonding portion.

3. The printed circuit board according to claim 2, wherein a lower surface of the bonding portion is substantially coplanar with a lower surface of the insulating layer and a lower surface of the metal via.

4. The printed circuit board according to claim 2, wherein an end of the wire portion is disposed on a level between a center of the insulating layer and the upper surface of the insulating layer based on the thickness direction.

5. The printed circuit board according to claim 1, wherein the metal via includes a first metal layer but does not include a seed metal layer.

6. The printed circuit board according to claim 1, further comprising:
first and second metal wirings disposed on the upper surface and the lower surface of the insulating layer, respectively, and connected to each other through the metal via.

7. The printed circuit board according to claim 6, wherein the first metal wiring comprises:
a first seed metal layer configured to cover an upper surface of each of the insulating layer and the metal via; and
a second metal layer configured to cover an upper surface of the first seed metal layer and to be thicker than the first seed metal layer, and
the second metal wiring comprises:
a second seed metal layer configured to cover a lower surface of each of the insulating layer, the metal via and the metal wire; and
a third metal layer configured to cover a lower surface of the second seed metal layer and to be thicker than the second seed metal layer.

8. The printed circuit board according to claim 1, wherein the insulating layer includes a glass substrate,
the metal wire includes an alloy including at least one of copper (Cu), gold (Au), silver (Ag), or palladium (Pd), and
the metal via includes copper (Cu).

9. The printed circuit board according to claim 1, wherein the through-hole is tapered so that a width of an upper end thereof is larger than a width of a lower end thereof on a cross-section.

10. The printed circuit board according to claim 1, wherein the through-hole is tapered so that a width of a lower end thereof is larger than a width of an upper end thereof on a cross-section.

11. The printed circuit board according to claim 1, wherein the through-hole is tapered to both sides so that a width of each of an upper end and a lower end thereof is larger than a width of a certain interior between the upper end and the lower end thereof on a cross-section.

12. A printed circuit board comprising:
an insulating layer having a through-hole;
a metal wire disposed inside the through-hole;
a first metal layer filling the through-hole and covering the metal wire;
a first seed metal layer disposed on an upper surface of each of the insulating layer and the first metal layer;
a second seed metal layer disposed on a lower surface of each of the insulating layer and the first metal layer;
a second metal layer disposed on an upper surface of the first seed metal layer; and
a third metal layer disposed on a lower surface of the second seed metal layer.

13. The printed circuit board according to claim 12, wherein the metal wire includes a bonding portion and a wire portion connected to the bonding portion,
an upper surface of the wire portion is spaced apart from the first seed metal layer, and
a lower surface of the bonding portion is in contact with the second seed metal layer.

14. The printed circuit board according to claim 12, wherein an upper surface of the first metal layer is substantially coplanar with the upper surface of the insulating layer, and
a lower surface of the first metal layer is substantially coplanar with the lower surface of the insulating layer.

15. The printed circuit board according to claim 14, wherein the first metal layer is a single layer, and
the first metal layer is in contact with a wall surface of the through-hole.

16. The printed circuit board according to claim 12, wherein the insulating layer includes a glass substrate,
the metal wire includes a palladium (Pd)-copper (Cu) alloy,
each of the first and second seed metal layers includes copper (Cu), and
each of the first to third metal layers includes copper (Cu).

17. A printed circuit board comprising:
an insulating layer;
a through-hole penetrating between an upper surface and a lower surface of the insulating layer opposing in a thickness direction;
a first metal portion disposed inside the through-hole; and
a second metal portion filling the through-hole and covering the first metal portion,
wherein a thickness of the first metal portion in the thickness direction is larger than a width of the first metal portion in a width direction perpendicular to the thickness direction.

18. The printed circuit board according to claim 17, further comprising:
first and second metal wirings disposed on the upper surface and the lower surface of the insulating layer, respectively, and connected to each other through the second metal portion.

19. The printed circuit board according to claim 18, wherein the first metal wiring comprises:
a first seed metal layer covering an upper surface of each of the insulating layer and the second metal portion; and
a second metal layer covering an upper surface of the first seed metal layer and to be thicker than the first seed metal layer, and
the second metal wiring comprises:
a second seed metal layer covering a lower surface of each of the insulating layer and the second metal portion; and
a third metal layer covering a lower surface of the second seed metal layer and to be thicker than the second seed metal layer.

20. The printed circuit board according to claim 19, wherein the first metal portion is bonded to the second seed metal layer, and
an end of the first metal portion is spaced apart from the upper surface of the second metal portion.
